(19) United States
(12) Patent Application Publication
(10) Pub. No.: US 2026/0362904 A1
(43) Pub. Date: Nov. 12, 2026

(54) DISPLAY PANEL AND DISPLAY APPARATUS

(71) Applicant: Hefei Visionox Technology Co., Ltd., Hefei (CN)

(72) Inventor: Zhiwei ZHOU, Hefei (CN)

(73) Assignee: Hefei Visionox Technology Co., Ltd., Hefei (CN)

(21) Appl. No.: 19/412,742

(22) Filed: Dec. 8, 2025

(30) Foreign Application Priority Data
May 8, 2025 (CN) 202510587322.9

(51) Int. Cl. H10K 59/122; H10K 59/80

(52) U.S. Cl. CPC H10K 59/122; H10K 59/873

(57) ABSTRACT

The present application discloses a display panel and a display apparatus. The display panel includes a substrate, an isolation structure, light-emitting devices, and encapsulation portions. The isolation structure is disposed on one side of the substrate and defines isolation openings in an enclosing manner, and includes a first sublayer and a second sublayer located on a side of the first sublayer facing away from the substrate. At least part of a structure of the light-emitting device is located within the corresponding isolation opening. The encapsulation portion is disposed on a side of the corresponding light-emitting device facing away from the substrate, and includes a first sub-portion and a second sub-portion, the first sub-portion covering the side of the light-emitting device facing away from the substrate, and the second sub-portion covering the corresponding sidewall.

### CROSS-REFERENCE TO RELATED APPLICATIONS

The present application claims priority to Chinese Patent Application No. 202510587322.9, filed on May 8, 2025 and entitled "DISPLAY PANEL AND DISPLAY APPARATUS", the disclosure of which is incorporated herein by reference in its entirety.

### FIELD

The present application relates to the field of display, and in particular to a display panel and a display apparatus.

### BACKGROUND

Organic light-emitting diodes (OLEDs) and flat panel display apparatuses based on technologies such as light-emitting diodes (LEDs) have been widely used in various consumer electronics such as mobile phones, televisions, notebook computers, and desktop computers, and predominate in display apparatuses thanks to their advantages such as high image quality, energy efficiency, slim design, and a wide range of applications.

During the preparation of conventional display panels, light-emitting pixel patterning is usually implemented by means of a fine metal mask (FMM). FMM technology is mature and has rich experience in mass production. However, FMM technology also has problems such as limited accuracy, high development costs, and long development cycle. Fine metal mask-free technology eliminates the limitations of conventional OLED processes on display size, resolution, and other screen performances, and has the advantages of high performance, full-size coverage, and agile delivery. Reference can be made to relevant contents of the fine metal mask-free technology recited in Chinese patents CN 118251982 A, CN 115666161 A, CN 116648095 A, CN 117062489 A, CN 118678742 A, CN 118785761 A, CN 115224220 A, CN 118678729 A, CN 118660529 A, and CN 118660589 A.

However, the usage performance of conventional OLED display products needs to be improved.

### SUMMARY

Embodiments of the present application provide a display panel and a display apparatus, with the aim of improving the usage performance of OLED display products.

A display panel is provided according to an embodiment of the present application. The display panel includes a substrate, an isolation structure, light-emitting devices, and encapsulation portions. The isolation structure is disposed on one side of the substrate and defines isolation openings in an enclosing manner, and includes a first sublayer and a second sublayer located on a side of the first sublayer facing away from the substrate, the first sublayer having sidewalls facing the isolation openings, and the second sublayer having flange portions protruding from the first sublayer toward the isolation openings. At least part of a structure of each light-emitting device is located within a corresponding one of the isolation openings. Each of the encapsulation portions is disposed on a side of a corresponding one of the light-emitting devices facing away from the substrate, and includes a first sub-portion and a second sub-portion, the first sub-portion covering the side of the light-emitting device facing away from the substrate, and the second sub-portion covering a corresponding one of the sidewalls; where the second sub-portion has a first thickness which is less than a protruding length of the flange portion.

According to an embodiment of the present application, a ratio of the first thickness to the protruding length of the flange portion is less than or equal to 0.5.

According to any of the foregoing embodiments of the present application, the ratio of the first thickness to the protruding length of the flange portion is greater than or equal to 0.1.

According to any of the foregoing embodiments of the present application, the first thickness is greater than or equal to 0.05 microns.

According to any of the foregoing embodiments of the present application, the first thickness is greater than or equal to 0.1 microns, and/or the first thickness is less than or equal to 0.5 microns.

According to any of the foregoing embodiments of the present application, each of the encapsulation portions further includes a third sub-portion which is at least partially located on a side of the second sublayer facing the substrate and at least partially attached to the flange portion.

According to any of the foregoing embodiments of the present application, the first sub-portion, the second sub-portion and the third sub-portion define a groove in an enclosing manner, and an orthographic projection of the groove on the substrate at least partially overlaps with an orthographic projection of the second sublayer on the substrate.

According to any of the foregoing embodiments of the present application, the third sub-portion has a second thickness, and a ratio of the first thickness to the second thickness is less than or equal to 1 and greater than or equal to 0.3.

According to any of the foregoing embodiments of the present application, a ratio of the second thickness to the first thickness is less than or equal to 0.8.

According to any of the foregoing embodiments of the present application, the second thickness is greater than or equal to 0.3 microns, and/or the second thickness is less than or equal to 1.2 microns.

According to any of the foregoing embodiments of the present application, the first sub-portion includes a central section and a peripheral section connected to each other, the peripheral section being located on a circumferential side of the central section, and a thickness of the peripheral section being less than or equal to a thickness of the central section.

According to any of the foregoing embodiments of the present application, the peripheral section is connected between the central section and the second sub-portion, and the second sub-portion is located on a circumferential side of the peripheral section.

According to any of the foregoing embodiments of the present application, the central section has a third thickness, and a ratio of the first thickness to the third thickness is less than or equal to 0.35 and greater than or equal to 0.15.

According to any of the foregoing embodiments of the present application, the third thickness is greater than or equal to 0.6 microns and less than or equal to 2.2 microns.

According to any of the foregoing embodiments of the present application, each of the encapsulation portions further includes a fourth sub-portion extending to a side of the isolation structure facing away from the substrate, the fourth sub-portion having a fourth thickness, and a ratio of the first thickness to the fourth thickness being less than or equal to 0.35 and greater than or equal to 0.15.

According to any of the foregoing embodiments of the present application, the fourth thickness is greater than or equal to 0.6 microns and less than or equal to 2.2 microns.

According to any of the foregoing embodiments of the present application, the isolation structure further includes a third sublayer located on a side of the first sublayer facing the substrate, and an orthographic projection of the first sublayer on the substrate is located within an orthographic projection of the third sublayer on the substrate.

According to any of the foregoing embodiments of the present application, a material of the first sublayer includes a conductive material, and/or a material of the third sublayer includes a conductive material.

According to any of the foregoing embodiments of the present application, each of the light-emitting devices includes a first electrode, an emitting layer and a second electrode which are stacked in a direction away from the substrate.

According to any of the foregoing embodiments of the present application, the second electrode is electrically connected to the isolation structure.

According to any of the foregoing embodiments of the present application, the display panel further includes a pixel definition layer disposed on one side of the substrate and defining pixel openings in an enclosing manner, where each of the pixel openings is in communication with a corresponding one of the isolation openings, and at least part of a structure of each of the light-emitting devices is located in a corresponding one of the pixel openings; and an orthographic projection of the pixel opening on the substrate is located within the orthographic projection of the first sub-portion on the substrate.

According to any of the foregoing embodiments of the present application, the pixel definition layer is located on a side of the isolation structure close to the substrate.

According to any of the foregoing embodiments of the present application, a material of the encapsulation portion includes an inorganic material.

According to any of the foregoing embodiments of the present application, the display panel further includes a second encapsulation layer disposed on sides of the encapsulation portions facing away from the substrate.

According to any of the foregoing embodiments of the present application, the display panel further includes a third encapsulation layer disposed on a side of the second encapsulation layer facing away from the substrate.

According to any of the foregoing embodiments of the present application, a material of the second encapsulation layer includes an organic material, and/or a material of the third encapsulation layer includes an inorganic material.

A display panel is further provided according to an embodiment in the first aspect of the present application. The display panel includes a substrate, an isolation structure, light-emitting devices, and encapsulation portions. The isolation structure is disposed on one side of the substrate and defines isolation openings in an enclosing manner, and includes a first sublayer and a second sublayer located on a side of the first sublayer facing away from the substrate, the first sublayer having sidewalls facing the isolation openings, and the second sublayer protruding from the first sublayer toward the isolation openings. At least part of a structure of each light-emitting device is located within a corresponding one of the isolation openings. Each of the encapsulation portions is disposed on a side of a corresponding one of the light-emitting devices facing away from the substrate, and includes a first sub-portion and a second sub-portion, the first sub-portion covering the side of the light-emitting device facing away from the substrate, and the second sub-portion covering a corresponding one of the sidewalls; where the second sub-portion has a first thickness which is greater than or equal to 0.05 microns and less than or equal to 0.5 microns.

According to an implementation in the first aspect of the present application, the first thickness is greater than or equal to 0.1 microns.

According to any of the foregoing embodiments of the present application, each of the encapsulation portions further includes a third sub-portion which is at least partially located on a side of the second sublayer facing the substrate.

According to any of the foregoing embodiments of the present application, the first sub-portion, the second sub-portion and the third sub-portion define a groove in an enclosing manner, and an orthographic projection of the groove on the substrate at least partially overlaps with an orthographic projection of the second sublayer on the substrate.

According to any of the foregoing embodiments of the present application, the third sub-portion has a second thickness, and a ratio of the first thickness to the second thickness is less than or equal to 1 and greater than or equal to 0.3.

According to any of the foregoing embodiments of the present application, a ratio of the second thickness to the first thickness is less than or equal to 0.8.

According to any of the foregoing embodiments of the present application, the second thickness is greater than or equal to 0.3 microns, and/or the second thickness is less than or equal to 1.2 microns.

A display apparatus is provided according to an embodiment in the second aspect of the present application. The display apparatus includes a display panel according to any of the embodiments described above.

The display panel according to this embodiment of the present application includes a substrate, an isolation structure, light-emitting devices, and encapsulation portions. Each of the encapsulation portions includes a first sub-portion and a second sub-portion, the first sub-portion covering a corresponding one of the light-emitting devices to encapsulate and protect the light-emitting device, making it difficult for intrusion of moisture into the light-emitting device through the encapsulation portion, thereby prolonging the service life of the light-emitting device. The second sub-portion is connected to the first sub-portion and extends to a corresponding one of sidewalls of the isolation structure, which increases the encapsulation area of the encapsulation portion to extend the water and oxygen intrusion path and thus further increase the difficulty of intrusion of water and oxygen, thereby improving the reliability of the light-emitting device. A good encapsulation effect is achieved by means of the encapsulation portion that overlaps with the sidewall and with the surface of the second sublayer facing the substrate, and setting the first thickness to be less than the protruding length of the flange portion can effectively increase the overall length of overlap of the encapsulation portion with the sidewall of the first sublayer and with the surface of the second sublayer facing the substrate, which reduces the risk of detachment of the encapsulation portion from the isolation structure and further improves the encapsulation effect, thereby improving the reliability and usage performance of the display panel.

### BRIEF DESCRIPTION OF THE DRAWINGS

Embodiments of the present application are becoming more clear upon reading the following detailed description of non-limiting embodiments with reference to the drawings, where identical or similar reference numerals indicate identical or similar features and the drawings are not drawn to scale.

FIG. 1 is a schematic structural top view of an isolation structure in a display panel according to an embodiment of the present application;

FIG. 2 is a first partial structural cross-sectional view of a display panel according to an embodiment of the present application;

FIG. 3 is a second partial structural cross-sectional view of a display panel according to an embodiment of the present application;

FIG. 4 is a third partial structural cross-sectional view of a display panel according to an embodiment of the present application; and

FIG. 5 is a fourth partial structural cross-sectional view of a display panel according to an embodiment of the present application.

### List of reference signs

1. Substrate;

2. Pixel definition layer; 20. Pixel opening;

3. Isolation structure; 30. Isolation opening; 31. First sublayer; 32. Second sublayer; 321. Flange portion; 33. Third sublayer;

4. Light-emitting device; 40. Emitting layer; 41. First electrode; 42. Second electrode;

50. Encapsulation portion; 51. First sub-portion; 511. Central section; 512. Peripheral section; 52. Second sub-portion; 53. Third sub-portion; 54. Fourth sub-portion; 501. Groove;

6. Second encapsulation layer; 7. Third encapsulation layer;

D1. First thickness; D2. Second thickness; D3. Third thickness; D4. Fourth thickness.

### DETAILED DESCRIPTION OF THE EMBODIMENTS

Features and exemplary embodiments of the present application will be described in detail below. In order to make the embodiments of the present application clearer, the present application will be further described in detail below with reference to the accompanying drawings and specific embodiments. It should be understood that the specific embodiments described herein are merely configured to explain the present application and are not configured to limit the present application. The present application may be implemented without part of these specific details. The following description of the embodiments is merely to provide a better understanding of the present application by illustrating examples of the present application.

It should be noted that, herein, relational terms such as "first" and "second" are only used to distinguish one entity or operation from another entity or operation, and do not necessarily require or imply that such an actual relationship or order exists between these entities or operations. Furthermore, the terms "comprises", "includes" or any other variant thereof are intended to cover non-exclusive inclusion, and a process, method, object or device including a series of elements not only includes those elements, but further includes other elements not explicitly listed, or further includes elements inherent to such process, method, object or device. If no more limitations are made, an element limited by "including..." does not exclude other identical elements existing in the process, the method, the article, or the device which includes the element.

It should be understood that in the description of the structure of a component, a layer or region referred as being located "above" or "over" another layer or region may be directly on the other layer or region, or there may be other layers or regions between the layer or region and the other layer or region. Moreover, when the component is turned over, the layer or region is located "below" or "under" the other layer or region.

Embodiments of the present application provide a display panel and a display apparatus. The embodiments of the display panel and the display apparatus will be described below with reference to the drawings.

The embodiments of the present application provide a display panel, which may be an organic light-emitting diode (OLED) display panel.

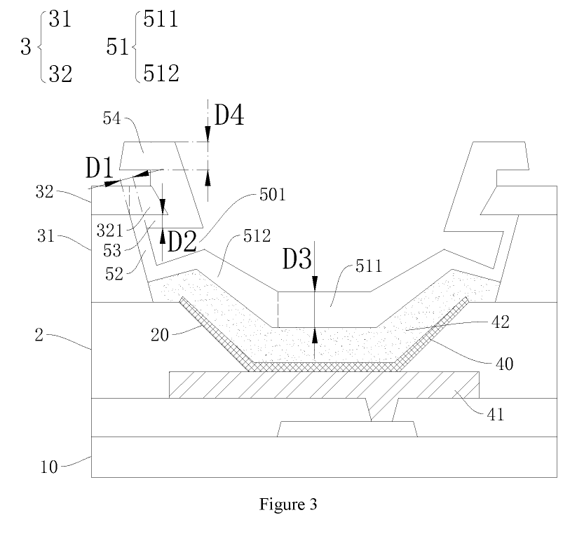

Referring to FIGS. 1-3, a display panel is provided according to an embodiment of the present application. The display panel includes a substrate 1, an isolation structure 3, light-emitting devices 4, and encapsulation portions 50. The isolation structure 3 is disposed on one side of the substrate 1 and defines isolation openings 30 in an enclosing manner. The isolation structure 3 includes a first sublayer 31 and a second sublayer 32 located on a side of the first sublayer 31 facing away from the substrate 1. The first sublayer 31 has sidewalls facing the isolation openings 30, and the second sublayer 32 has flange portions 321 protruding from the first sublayer 31 toward the isolation openings 30. At least part of a structure of each light-emitting device 4 is located within the corresponding isolation opening 30. Each encapsulation portion 50 is disposed on a side of the corresponding light-emitting device 4 facing away from the substrate 1. The encapsulation portion 50 includes a first sub-portion 51 and a second sub-portion 52, the first sub-portion 51 covering the side of the light-emitting device 4 facing away from the substrate 1, and the second sub-portion 52 covering the corresponding sidewall. The second sub-portion 52 has a first thickness D1. The first thickness D1 is less than a protruding length of the flange portion 321.

The substrate 1 may be arranged in a variety of ways. In one embodiment, the substrate 1 includes a base substrate and a drive circuit disposed on a side of the base substrate facing the isolation structure 3. The drive circuit may include a transistor, a storage capacitor, drive signal lines for connecting devices, etc. The transistor includes a semiconductor, a gate, and source/drain. The storage capacitor includes a first plate and a second plate.

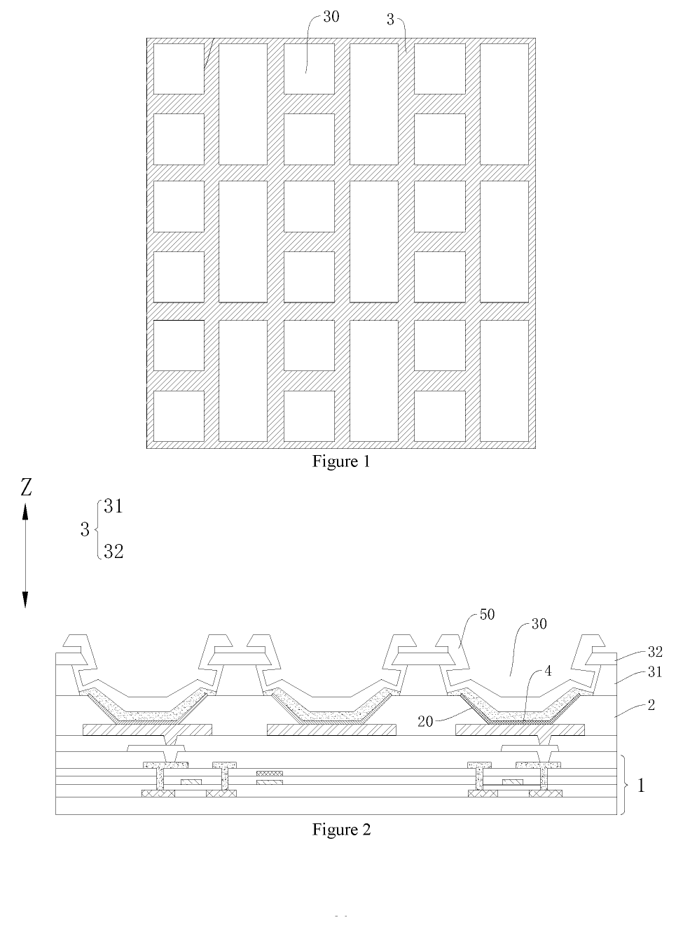

In one embodiment, an orthographic projection of the light-emitting device 4 on the substrate 1 at least partially overlaps with an orthographic projection of the corresponding isolation opening 30 on the substrate 1. In one embodiment, in the present application, the direction of an orthographic projection of a certain structure on the substrate 1 may refer to the Z-axis direction in FIG. 2, and the direction indicated by the Z-axis may also be a thickness direction of the display panel.

In one embodiment, in the present application, an orthographic projection of a structure such as “opening”, “via” or “recess” on the substrate 1 can be understood as a region correspondingly enclosed by the orthographic projection of the structure forming the “opening”, “via” or “recess” in an enclosing manner on the substrate 1.

In one embodiment, as shown in FIG. 1, the isolation structure 3 may be grid-shaped, and the isolation structure 3 defines isolation openings 30 in an enclosing manner to define emitting regions of the display panel, which facilitates the division of subpixels of the display panel by the isolation structure 3.

The isolation structure 3 is disposed on one side of the substrate 1 and defines a plurality of isolation openings 30 in an enclosing manner. Each isolation opening 30 can be used to accommodate at least part of the corresponding light-emitting device 4. The isolation structure 3 can be used to divide the subpixels of the display panel. The isolation structure 3 is disposed on the substrate 1 and defines the plurality of isolation openings 30 in an enclosing manner and can separate a light-emitting material into portions of an emitting layer 40 disconnected from each other, thereby reducing crosstalk between charge carriers in the emitting layer 40 and improving the display effect of the display panel. Moreover, the emitting layer 40 may be prepared without the use of a precision mask, which can reduce the development and use of the precision mask and lower preparation costs.

A plurality of isolation openings 30, a plurality of light-emitting devices 4 and plurality of encapsulation portions 50 may be provided. In one embodiment, the isolation openings 30 are disposed in a one-to-one correspondence with the light-emitting devices 4 and the encapsulation portions 50. Adjacent encapsulation portions 50 may be spaced apart or may overlap.

The first thickness D1 may be understood as a stacking thickness of the second sub-portion 52 in a direction perpendicular to the surface of the corresponding sidewall of the first sublayer 31. The first thickness D1 is not completely uniform. During measurement of thicknesses of the second sub-portion 52 at various positions, the thicknesses at the positions may be different. That is, the first thickness D1 is in a range, with a maximum value, a minimum value and an average value. The first thickness D1 being less than the protruding length of the flange portion 321 can be understood as that the thicknesses of the second sub-portion 52 at various positions are all less than the protruding length of the flange portion 321.

A display panel is provided according to an embodiment of the present application. The display panel includes a substrate 1, an isolation structure 3, light-emitting devices 4, and encapsulation portions 50. Each encapsulation portion 50 includes a first sub-portion 51 and a second sub-portion 52, the first sub-portion 51 covering the corresponding light-emitting device 4 to encapsulate and protect the light-emitting device 4, making it difficult for intrusion of moisture into the light-emitting device 4 through the encapsulation portion 50, thereby prolonging the service life of the light-emitting device 4. The second sub-portion 52 is connected to the first sub-portion 51 and extends to the corresponding sidewall of the isolation structure 3, which increases the encapsulation area of the encapsulation portion 50 to extend the water and oxygen intrusion path and thus further increase the difficulty of intrusion of water and oxygen, thereby improving the reliability of the light-emitting device 4. A good encapsulation effect is achieved by means of the encapsulation portion 50 that overlaps with the sidewall and with the surface of the second sublayer 32 facing the substrate 1, and setting the first thickness D1 to be less than the protruding length of the flange portion 321 can effectively increase the overall length of overlap of the encapsulation portion 50 with the sidewall of the first sublayer 31 and with the surface of the second sublayer 32 facing the substrate 1, which reduces the risk of detachment of the encapsulation portion 50 from the isolation structure 3 and further improves the encapsulation effect, thereby improving the reliability and usage performance of the display panel.

In one embodiment, each light-emitting device 4 includes a first electrode 41, an emitting layer 40 and a second electrode 42 which are stacked. One of the first electrode 41 and the second electrode 42 may serve as an anode, and the other may serve as a cathode, to drive the emitting layer 40 to emit light. In this embodiment of the present application, the first electrodes 41 are used as anodes of the display panel, and the second electrodes 42 are used as cathode of the display panel.

The first electrode 41 of the light-emitting device 4 is located on a side of the isolation structure 3 close to the substrate 1, and at least part of the first electrode 41 is at least exposed from the isolation opening 30, and the emitting layer 40 of the light-emitting device 4 overlaps with the first electrode 41.

In one embodiment, an orthographic projection of the isolation opening 30 on the substrate 1 at least partially overlaps with an orthographic projection of the first electrode 41 on the substrate 1, and the emitting layer 40 prepared subsequently overlaps with the first electrode 41. The first sublayer 31 and the second sublayer 32 are sequentially stacked to form the isolation structure 3. An orthographic projection of a side, away from the substrate 1, of the first sublayer 31 disposed close to the substrate 1 on the base substrate is located within an orthographic projection of the second sublayer 32 on the base substrate, the second sublayer 32 covers a surface of the first sublayer 31 away from the substrate 1, and then the first sublayer 31 is recessed relative to the second sublayer 32 in a direction away from the isolation opening 30. During preparation of the emitting layer 40, the light-emitting material has a large drop at an edge of the isolation opening 30, and the first sublayer 31 is recessed relative to the second sublayer 32, making it difficult for the light-emitting material to be continuous at the edge of the isolation opening 30, resulting in breakage. The light-emitting material breaks to form portions of the emitting layer 40 isolated from each other.

In one embodiment, one or more of a hole inject layer (HIL), a hole transport layer (HTL) and an electron blocking layer may be provided between the emitting layer 40 (EML) and the first electrode 41, and one or more of a hole blocking layer, an electron inject layer (EIL) and an electron transport layer (ETL) may be provided between the emitting layer 40 and the second electrode 42.

In one embodiment, a ratio of the first thickness D1 to the protruding length of the flange portion 321 is less than or equal to 0.5.

For example, the first thickness D1 may be 0.08 microns, and the protruding length of the flange portion 321 may be 0.2 microns, 0.3 microns, 0.5 microns, etc.

In these embodiments, the overlap of the second sub-portion 52 with the sidewall can increase the adhesion between the encapsulation portion 50 and the isolation structure 3. Moreover, since the second sub-portion 52 has a certain thickness that is less than or equal to half of the protruding length of the flange portion 321, the flange portion 321 reserves at least half of its length to overlap with other portions of the encapsulation portion 50, which further increases the adhesion between the encapsulation portion 50 and the isolation structure 3. In this embodiment, the effective length of overlap of the encapsulation portion 50 with the isolation structure 3 can be increased, thereby improving the encapsulation performance.

In one embodiment, the ratio of the first thickness D1 to the protruding length of the flange portion 321 is greater than or equal to 0.1.

In these embodiments, it is possible to solve the problem that the second sub-portion 52 has poor encapsulation performance due to the second sub-portion 52 being too thin, resulting in easier intrusion of water and oxygen into the light-emitting device 4 through the second sub-portion 52, and also solve the problem that the second sub-portion 52 has poor structural strength due to the second sub-portion 52 being too thin, resulting in the second sub-portion 52 being prone to film damage or film detachment after the sidewall of the isolation structure 3 climbs and is stretched and thinned.

For example, the first thickness D1 is greater than or equal to 0.05 microns.

In one embodiment, the first thickness D1 is greater than or equal to 0.1 microns. In one embodiment, the first thickness D1 is less than or equal to 0.5 microns. For example, the first thickness D1 may be 0.1 microns, 0.2 microns, 0.3 microns, 0.4 microns, 0.5 microns, etc.

In these embodiments, the first thickness D1 is greater than or equal to 0.1 microns, and the second sub-portion 52 has a certain structural strength and is not easily damaged or detached. The first thickness D1 is less than or equal to 0.5 microns, which is conducive to the overlap of the encapsulation portion 50 with the surface of the flange portion 321 close to the substrate 1, thereby increasing the length of overlap of the encapsulation portion 50 with the isolation structure 3. In one embodiment, the protruding length of the flange portion 321 is greater than or equal to 0.2 microns, which is conducive to separation of the light-emitting material, and the protruding length of the flange portion 321 is less than or equal to 2 microns, which is conducive to increasing the proportion of area of the isolation opening 30 to obtain a high pixels-per-inch (PPI) display panel.

In some embodiments, the encapsulation portion 50 further includes a third sub-portion 53. The third sub-portion 53 is at least partially located on a side of the second sublayer 32 facing the substrate 1 and at least partially attached to the flange portion 321.

In these embodiments, the third sub-portion 53 being at least partially attached to the flange portion 321 can effectively increase the length of overlap of the encapsulation portion 50 with the isolation structure 3, which improves the encapsulation effect, and thus improves the reliability and usage performance of the display panel and reduces adverse conditions such as dark spots in display caused by encapsulation failure.

In one embodiment, the first sub-portion 51, the second sub-portion 52 and the third sub-portion 53 define a groove 501 in an enclosing manner, and an orthographic projection of the groove 501 on the substrate 1 at least partially overlaps with an orthographic projection of the second sublayer 32 on the substrate 1.

The orthographic projection of the groove 501 on the substrate 1 at least partially overlapping with the orthographic projection of the second sublayer 32 on the substrate 1 can also be understood as that at least part of the groove 501 is located directly below the second sublayer 32.

In these embodiments, the encapsulation portion 50 covers the sidewall of the first sublayer 31 and the surface of the flange portion 321 close to the substrate 1 along the contour of the isolation structure 3, and is thin and does not completely fill the concave portion of the first sublayer 31 relative to the second sublayer 32, which can effectively increase the effective length of overlap of the encapsulation portion 50 with the isolation structure 3, thereby further improving the encapsulation effect.

In some embodiments, the third sub-portion 53 has a second thickness D2, and a ratio of the first thickness D1 to the second thickness D2 is less than or equal to 1 and greater than or equal to 0.3.

Compared with the sidewall of the first sublayer 31, during preparation, the encapsulation material is more likely to accumulate on a surface of a side of the flange portion 321 close to the substrate 1, and the second thickness D2 of the third sub-portion 53 is not less than the first thickness D1 of the second sub-portion 52. In one embodiment, a ratio of the second thickness D2 to the first thickness D1 is less than or equal to 0.8.

In these embodiments, the ratio of the first thickness D1 to the second thickness D2 is greater than or equal to 0.3, and the second sub-portion 52 has a certain structural strength and is not easily damaged or detached, and it is also possible to solve the problem that the second sub-portion 52 has poor encapsulation performance due to the second sub-portion 52 being too thin, resulting in easier intrusion of water and oxygen into the light-emitting device 4 through the second sub-portion 52.

In one embodiment, the second thickness D2 is greater than or equal to 0.3 microns. The second thickness D2 is greater than or equal to 0.3 microns, which can solve the problem that the third sub-portion 53 has poor encapsulation performance due to the second thickness D2 being too small, resulting in easier intrusion of water and oxygen into the light-emitting device 4 through the third sub-portion 53, and can also solve the problem that the third sub-portion 53 has poor structural strength due to the third sub-portion 53 being too thin, resulting in the third sub-portion 53 being prone to film damage or film detachment after being impacted.

In one embodiment, the second thickness D2 is less than or equal to 1.2 microns. The second thickness D2 is less than or equal to 1.2 microns, which can solve the problem that the third sub-portion 53 being too heavy due to the third sub-portion 53 being too thick, making it difficult for the third sub-portion 53 to adhere to the isolation structure 3 by the adhesion between the third sub-portion 53 and the isolation structure 3, resulting in the third sub-portion 53 being prone to film detachment.

For example, the second thickness D2 may be 0.3 microns, 0.5 microns, 0.7 microns, 1 micron, 1.2 microns, etc.

In some embodiments, the first sub-portion 51 includes a central section 511 and a peripheral section 512 connected to each other. The peripheral section 512 is located on a circumferential side of the central section 511, and a thickness of the peripheral section 512 is less than or equal to a thickness of the central section 511.

In these embodiments, the thickness of the central section 511 is greater than or equal to the thickness of the peripheral section 512, and the central section 511 is thicker and covers the light-emitting device 4, to encapsulate and protect the light-emitting device 4. The central section 511 covers at least part of the light-emitting device 4, and the central section 511 is relatively thick. On the one hand, it is possible to improve the encapsulation performance of the central section 511, thereby improving the reliability of the light-emitting device 4. On the other hand, it is also possible to achieve good structural strength to improve the impact resistance of the central section 511, to achieve better protection for the light-emitting device 4. The peripheral section 512 is thinner and has higher flexibility, and the peripheral section 512 fits better with the edge of the light-emitting device 4, to further improve the encapsulation effect of the encapsulation portion 50 on the light-emitting device 4.

In one embodiment, the peripheral section 512 is connected between the central section 511 and the second sub-portion 52, and the second sub-portion 52 is located on a circumferential side of the peripheral section 512. The peripheral section 512 is in a closed ring shape, and the second sub-portion 52 is also in a closed ring shape, and the encapsulation portion 50 forms a complete encapsulation, which avoids formation of unencapsulated corners, thereby improving the encapsulation effect.

In some embodiments, the central section 511 has a third thickness D3, and a ratio of the first thickness D1 to the third thickness D3 is less than or equal to 0.35 and greater than or equal to 0.15.

During preparation of the encapsulation portion 50, since the isolation structure 3 has a greater height difference, the encapsulation portion 50 climbs over the sidewall of the isolation structure 3 and the encapsulation portion 50 is stretched, thereby forming a second sub-portion 52 that is thinner. The second sub-portion 52 is stretched and thinned, has higher flexibility, and fits better with the isolation structure 3, to further improve the encapsulation effect of the encapsulation portion 50 on the light-emitting device 4.

In these embodiments, the first thickness D1 of the second sub-portion 52 is greater than or equal to 0.15 times the third thickness of the central section 511, which solves the problem that the second sub-portion 52 has poor encapsulation performance due to the second sub-portion 52 being too thin, resulting in easier intrusion of water and oxygen into the light-emitting device 4 through the second sub-portion 52, and also solves the problem that the second sub-portion 52 has poor structural strength due to the second sub-portion 52 being too thin, resulting in the second sub-portion 52 being prone to film damage or film detachment after the sidewall of the isolation structure 3 climbs and is stretched and thinned. The first thickness D1 of the second sub-portion 52 is less than or equal to 0.35 times the thickness of the central section 511, which solves the problem that the second sub-portion 52 has poor flexibility due to the second sub-portion 52 being too thick, resulting in poor fitting effect of the second sub-portion 52 with the isolation structure 3 at a climbing position of the isolation structure 3, which is prone to formation of air holes or other defects.

In some embodiments, the third thickness D3 is greater than or equal to 0.6 microns and less than or equal to 2.2 microns. For example, the third thickness D3 may be 0.6 microns, 1 micron, 1.2 microns, 1.8 microns, 2.2 microns, etc.

In these embodiments, the third thickness D3 of the central section 511 is greater than or equal to 0.6 microns, which solves the problem that the central section 511 has poor encapsulation performance due to the central section 511 being too thin, resulting in easy intrusion of water and oxygen into the light-emitting device 4 through the central section 511, and can also solve the problem that the central section 511 has poor structural strength due to the central section 511 being too thin, resulting in film damage or film detachment after being impacted. The third thickness D3 of the central section 511 is less than or equal to 2.2 μm, which can solve the problems of excessive material consumption and high material cost of the central section 511 and increased overall thickness of the display panel due to the central section 511 being too thick.

In some embodiments, the encapsulation portion 50 further includes a fourth sub-portion 54 extending to a side of the isolation structure 3 facing away from the substrate 1. The fourth sub-portion 54 has a fourth thickness D4, and a ratio of the first thickness D1 to the fourth thickness D4 is less than or equal to 0.35 and greater than or equal to 0.15.

The fourth sub-portion 54 may be formed together with the first sub-portion 51. During preparation of the encapsulation material over the entire surface, the fourth sub-portion 54 and the first sub-portion 51 have similar forming conditions, and are both disposed on a relatively flat surface and are not shielded, and the thickness of the fourth sub-portion 54 may be similar to the thickness of the first sub-portion 51.

In one embodiment, the fourth thickness D4 is greater than or equal to 0.6 microns and less than or equal to 2.2 microns. For example, the fourth thickness D4 may be 0.6 microns, 1 micron, 1.2 microns, 1.8 microns, 2.2 microns, etc.

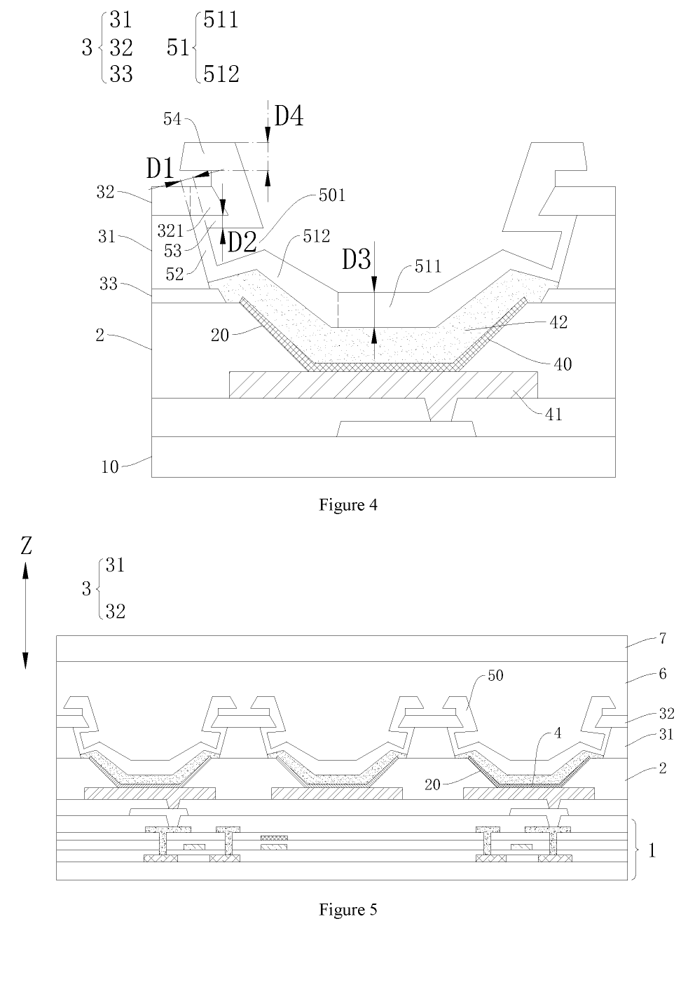

Referring to FIG. 4, in some embodiments, the isolation structure 3 further includes a third sublayer 33 located on a side of the first sublayer 31 facing the substrate 1, and an orthographic projection of the first sublayer 31 on the substrate 1 is located within an orthographic projection of the third sublayer 33 on the substrate 1. In one embodiment, a material of the third sublayer 33 may include a conductive material, and the second electrodes 42 may be connected to the third sublayer 33, and the second electrodes 42 of adjacent subpixels can be electrically connected by the third sublayer 33. By configuring the third sublayer 33 to protrude toward the isolation opening 30 beyond the first sublayer 31, the third sublayer 33 may have an increased size to facilitate connection of the second electrodes 42. A film thickness of the third sublayer 33 may be less than a film thickness of the first sublayer 31.

In one embodiment, a material of the first sublayer 31 includes a conductive material. In one embodiment, a material of the third sublayer 33 includes a conductive material. In one embodiment, the material of the second sublayer 32 is titanium (Ti) or molybdenum (Mo), the material of the first sublayer 31 is aluminum (Al), silver (Ag) or copper (Cu), and the material of the third sublayer 33 is titanium (Ti) or molybdenum (Mo). For example, the material of the isolation structure 3 is a three-layer metal composite material of Ti/Al/Ti (titanium/aluminum/titanium) or Ti/Al/Mo (titanium/aluminum/molybdenum). For example, the isolation structure 3 has an I-shaped cross section perpendicular to the substrate 1.

In some embodiments, the light-emitting device 4 includes a first electrode 41, an emitting layer 40 and a second electrode 42 which are stacked in a direction away from the substrate 1. In one embodiment, the second electrode 42 is electrically connected to the isolation structure 3. The isolation structure 3 is made of a conductive material, and the second electrode 42 of the light-emitting device 4 is electrically connected to the isolation structure 3. The isolation structure 3 separates an electrode material to form second electrodes 42 spaced apart from each other, and the second electrodes 42 spaced apart from each other are electrically connected by the isolation structure 3 to form a continuous electrode to ensure normal light emission of the emitting layer 40.

In one embodiment, during vapor deposition of the emitting layer 40 and the second electrodes 42 of the display panel, the second sublayer 32 can block at least part of materials for preparing the emitting layer 40 and the second electrodes 42, to separate the light-emitting material and the electrode material between adjacent subpixels, facilitate formation of a plurality of spaced portions of emitting layer 40 located within the isolation openings 30 and facilitate formation of a plurality of spaced second electrodes 42 located within the isolation openings 30, thereby eliminating the need for a high-precision mask during the vapor deposition of the emitting layer 40 and the second electrodes 42 of the display panel. For example, this eliminates the need for a fine metal mask (FMM) during the vapor deposition of the emitting layer 40 and the second electrodes 42, thus effectively reducing preparation costs of the display panel.

In some embodiments, the display panel further includes a pixel definition layer 2. The pixel definition layer 2 is disposed on one side of the substrate 1 and defines pixel openings 20 in an enclosing manner. The pixel openings 20 are in communication with the isolation openings 30, and at least part of a structure of each light-emitting device 4 is located in the corresponding pixel opening 20. An orthographic projection of the pixel opening 20 on the substrate 1 is located within an orthographic projection of the first sub-portion 51 on the substrate 1.

The plurality of pixel openings 20 may be disposed corresponding to the plurality of isolation openings 30, and each pixel opening 20 is in communication with the corresponding isolation opening 30.

The pixel definition layer 2 may be grid-shaped. The pixel definition layer 2 defines pixel openings 20 in an enclosing manner to define light-emitting regions of the display panel, which facilitates the division of subpixels in the display panel by the pixel definition layer 2.

In one embodiment, a material of the pixel definition layer 2 includes an inorganic insulating material. Inorganic materials have good density and moisture resistance, and can be prepared to be thin. For example, the material of the pixel definition layer 2 includes a silicon oxide compound and/or a silicon nitrogen compound, such as silicon oxide and silicon nitride.

In one embodiment, the emitting layer 40 is at least partially located in the corresponding pixel opening 20, the first electrode 41 is located on a side of the pixel definition layer 2 close to the substrate 1, and at least part of the first electrode 41 is exposed from the pixel opening 20 to facilitate electrical connection between the emitting layer 40 and the first electrode 41.

In one embodiment, the isolation structure 3 and the pixel definition layer 2 may be arranged in a variety of relative positional relationships. For example, the isolation structure 3 may be disposed on a side of the pixel definition layer 2 facing away from the substrate 1; or a clearance opening is formed in the pixel definition layer 2, and the isolation structure 3 may be located in the clearance opening. In this embodiment of the present application, the isolation structure 3 is located on the side of the pixel definition layer 2 facing away from the substrate 1, that is, the pixel definition layer 2 is located on the side of the isolation structure 3 close to the substrate 1.

Referring to FIG. 5, in some embodiments, the display panel further includes a first encapsulation layer. The first encapsulation layer includes a plurality of encapsulation portions 50 each located on a side of the corresponding light-emitting devices 4 away from the substrate 1. In one embodiment, the encapsulation portion 50 is located on a side of the second electrode 42 facing away from the substrate 1. The plurality of encapsulation portions 50 are spaced apart from each other. The plurality of encapsulation portions 50 may be arranged in a one-to-one correspondence with the plurality of light-emitting devices 4, and the light-emitting devices 4 of different emitting colors correspond to different encapsulation portions 50. In one embodiment, a material of the first encapsulation layer may include an inorganic material. The inorganic material has good density and moisture resistance, is thin, and also has a good encapsulation effect. The first encapsulation layer may be prepared by a chemical vapor deposition (CVD) process.

In one embodiment, the encapsulation portion 50 at least extends through the corresponding sidewall of the isolation structure 3, toward the corresponding isolation opening 30, to a side of the isolation structure 3 away from the substrate 1.

In one embodiment, the display panel further includes a second encapsulation layer 6 disposed on a side of the first encapsulation layer facing away from the substrate 1. In one embodiment, the display panel further includes a third encapsulation layer 7 disposed on a side of the second encapsulation layer 6 facing away from the substrate 1. A material of the second encapsulation layer 6 may include an organic material to impart the second encapsulation layer 6 relatively good flowability, and a surface of the side of the second encapsulation layer 6 facing away from the substrate 1 is flat. A material of the third encapsulation layer 7 may include an inorganic material to further improve the encapsulation effect of the display panel. In one embodiment, the second encapsulation layer 6 may be prepared by ink jet printing (IJP) technology. The third encapsulation layer 7 may be prepared by a chemical vapor deposition process.

In one embodiment, the display panel further includes a touch layer, a filter layer and a cover plate which are disposed on the third encapsulation layer 7. The touch layer may be used to enable touch operation of the display panel, the filter layer may be used to filter light to improve the display effect of the display panel, and the cover plate may be used to protect underlying film layers to increase the strength of the display panel.

Referring to FIGS. 1-5, a display panel is further provided according to an embodiment in the first aspect of the present application. The display panel includes a substrate 1, an isolation structure 3, light-emitting devices 4, and encapsulation portions 50. The isolation structure 3 is disposed on one side of the substrate 1 and defines isolation openings 30 in an enclosing manner. The isolation structure 3 includes a first sublayer 31 and a second sublayer 32 located on a side of the first sublayer 31 facing away from the substrate 1. The first sublayer 31 has sidewalls facing the isolation openings 30, and the second sublayer 32 protrudes from the first sublayer 31 toward the isolation openings 30. At least part of a structure of each light-emitting device 4 is located within the corresponding isolation opening 30. Each encapsulation portion 50 is disposed on a side of the corresponding light-emitting device 4 facing away from the substrate 1. The encapsulation portion 50 includes a first sub-portion 51 and a second sub-portion 52, the first sub-portion 51 covering the side of the light-emitting device 4 facing away from the substrate 1, and the second sub-portion 52 covering the corresponding sidewall. The second sub-portion 52 has a first thickness D1. The first thickness D1 is greater than or equal to 0.05 microns and less than or equal to 0.5 microns.

A display panel is further provided according to an embodiment of the present application. The display panel includes a substrate 1, an isolation structure 3, light-emitting devices 4, and encapsulation portions 50. Each encapsulation portion 50 includes a first sub-portion 51 and a second sub-portion 52, the first sub-portion 51 covering the corresponding light-emitting device 4 to encapsulate and protect the light-emitting device 4, making it difficult for intrusion of moisture into the light-emitting device 4 through the encapsulation portion 50, thereby prolonging the service life of the light-emitting device 4. The second sub-portion 52 is connected to the first sub-portion 51 and extends to the corresponding sidewall of the isolation structure 3, which increases the encapsulation area of the encapsulation portion 50 to extend the water and oxygen intrusion path and thus further increase the difficulty of intrusion of water and oxygen, thereby improving the reliability of the light-emitting device 4. The first thickness D1 is greater than or equal to 0.05 microns, and the second sub-portion 52 has a certain structural strength and is not easily damaged or detached. The first thickness D1 is less than or equal to 0.5 microns, which is conducive to the overlap of the encapsulation portion 50 with the surface of the flange portion 321 close to the substrate 1, thereby increasing the length of overlap of the encapsulation portion 50 with the isolation structure 3.

In one embodiment, the first thickness D1 is greater than or equal to 0.1 microns. In one embodiment, the protruding length of the flange portion 321 is greater than or equal to 0.2 microns, which is conducive to separation of the light-emitting material, and the protruding length of the flange portion 321 is less than or equal to 2 microns, which is conducive to increasing the proportion of area of the isolation opening 30 to obtain a high pixels-per-inch (PPI) display panel.

In some embodiments, the encapsulation portion 50 further includes a third sub-portion 53. The third sub-portion 53 is at least partially located on a side of the second sublayer 32 facing the substrate 1. The third sub-portion 53 being at least partially attached to the flange portion 321 can effectively increase the length of overlap of the encapsulation portion 50 with the isolation structure 3, which improves the encapsulation effect, and thus improves the reliability and usage performance of the display panel and reduces adverse conditions such as dark spots in display caused by encapsulation failure.

In some embodiments, the first sub-portion 51, the second sub-portion 52 and the third sub-portion 53 define a groove 501 in an enclosing manner, and an orthographic projection of the groove 501 on the substrate 1 at least partially overlaps with an orthographic projection of the second sublayer 32 on the substrate 1. The encapsulation portion 50 covers the sidewall of the first sublayer 31 and the surface of the flange portion 321 close to the substrate 1 along the contour of the isolation structure 3, and is thin and does not completely fill the concave portion of the first sublayer 31 relative to the second sublayer 32, which can effectively increase the effective length of overlap of the encapsulation portion 50 with the isolation structure 3, thereby further improving the encapsulation effect.

In some embodiments, the third sub-portion 53 has a second thickness D2, and a ratio of the first thickness D1 to the second thickness D2 is less than or equal to 1 and greater than or equal to 0.3. The ratio of the first thickness D1 to the second thickness D2 is greater than or equal to 0.3, and the second sub-portion 52 has a certain structural strength and is not easily damaged or detached, and it is also possible to solve the problem that the second sub-portion 52 has poor encapsulation performance due to the second sub-portion 52 being too thin, resulting in easier intrusion of water and oxygen into the light-emitting device 4 through the second sub-portion 52.

The display panel of the embodiment of the present application and the display panel of the above embodiments may be cross-referenced to each other. For example, the arrangement of the isolation structure 3, the light-emitting devices 4, the pixel definition layer 2 and other structures can be as described above. Therefore, the display panel further provided in the embodiments of the present application may have the beneficial effects of the display panel in any of the preceding embodiments, which will not be described in detail here.

This embodiment can be combined with some or all of the features of the above embodiments, which will not be described in detail here.

A display apparatus is provided according to an embodiment in a second aspect of the present application. The display apparatus includes a display panel of any of the embodiments described above. Since the display apparatus according to the embodiment in the second aspect of the present application includes the display panel according to any one of the above embodiments in the first aspect, the display apparatus according to the embodiment in the second aspect of the present application has the beneficial effects of the display panel according to any one of the above embodiments in the first aspect, and will not be described in detail here.

The display apparatus in the embodiments of the present application includes, but is not limited to, devices having a display function, such as a mobile phone, a personal digital assistant (PDA), a tablet computer, an e-book reader, a television, an access control system, a smart fixed-line telephone, or a console.

The embodiments of the present application as described above neither set forth all the details, nor do they limit the present application to only the described specific embodiments. Apparently, many modifications and variations can be made in light of the above description. The embodiments are selected and described in this specification to better explain the principles and practical applications of the present application. The present application is limited only by the claims and all the scopes and equivalents thereof.

What is claimed is:

1. A display panel, comprising:
a substrate;
an isolation structure disposed on one side of the substrate and defining isolation openings in an enclosing manner, the isolation structure comprising a first sublayer and a second sublayer located on a side of the first sublayer facing away from the substrate, the first sublayer having sidewalls facing the isolation openings, and the second sublayer having flange portions protruding from the first sublayer toward the isolation openings;
a plurality of light-emitting devices, at least part of a structure of each of the light-emitting devices being located within a corresponding one of the isolation openings; and
encapsulation portions, each of which is disposed on a side of a corresponding one of the light-emitting devices facing away from the substrate and comprises a first sub-portion and a second sub-portion, the first sub-portion covering the side of the light-emitting device facing away from the substrate, and the second sub-portion covering a corresponding one of the sidewalls;
wherein the second sub-portion has a first thickness which is less than a protruding length of the flange portion, and a ratio of the first thickness to the protruding length of the flange portion is greater than or equal to 0.1 and less than or equal to 0.5.

2. The display panel according to claim 1, wherein the first thickness is greater than or equal to 0.05 microns.

3. The display panel according to claim 1, wherein each of the encapsulation portions further comprises a third sub-portion which is at least partially located on a side of the second sublayer facing the substrate and at least partially attached to the flange portion.

4. The display panel according to claim 3, wherein the third sub-portion has a second thickness, and a ratio of the first thickness to the second thickness is less than or equal to 1 and greater than or equal to 0.3.

5. The display panel according to claim 1, wherein the first sub-portion comprises a central section and a peripheral section connected to each other, the peripheral section being located on a circumferential side of the central section, and a thickness of the peripheral section being less than or equal to a thickness of the central section.

6. The display panel according to claim 5, wherein the central section has a third thickness, and a ratio of the first thickness to the third thickness is less than or equal to 0.35 and greater than or equal to 0.15.

7. The display panel according to claim 1, wherein each of the encapsulation portions further comprises a fourth sub-portion extending to a side of the isolation structure facing away from the substrate, the fourth sub-portion having a fourth thickness, and a ratio of the first thickness to the fourth thickness being less than or equal to 0.35 and greater than or equal to 0.15.

8. The display panel according to claim 1, wherein the isolation structure further comprises a third sublayer located on a side of the first sublayer facing the substrate, and an orthographic projection of the first sublayer on the substrate is located within an orthographic projection of the third sublayer on the substrate.

9. The display panel according to claim 1, further comprising:
a pixel definition layer disposed on one side of the substrate and defining pixel openings in an enclosing manner, wherein each of the pixel openings is in communication with a corresponding one of the isolation openings, and at least part of a structure of each of the light-emitting devices is located in a corresponding one of the pixel openings; and an orthographic projection of the pixel opening on the substrate is located within the orthographic projection of the first sub-portion on the substrate.

10. The display panel according to claim 1, wherein a material of the encapsulation portion comprises an inorganic material.

11. A display panel, comprising:
a substrate;
an isolation structure disposed on one side of the substrate and defining isolation openings in an enclosing manner, the isolation structure comprising a first sublayer and a second sublayer located on a side of the first sublayer facing away from the substrate, the first sublayer having sidewalls facing the isolation openings, and the second sublayer protruding from the first sublayer toward the isolation openings;
a plurality of light-emitting devices, at least part of a structure of each of the light-emitting devices being located within a corresponding one of the isolation openings; and
encapsulation portions, each of which is disposed on a side of a corresponding one of the light-emitting devices facing away from the substrate and comprises a first sub-portion and a second sub-portion, the first sub-portion covering the side of the light-emitting device facing away from the substrate, and the second sub-portion covering a corresponding one of the sidewalls;
wherein the second sub-portion has a first thickness which is greater than or equal to 0.05 microns and less than or equal to 0.5 microns.

12. The display panel according to claim 11, wherein the first thickness is greater than or equal to 0.1 microns.

13. The display panel according to claim 11, wherein each of the encapsulation portions further comprises a third sub-portion which is at least partially located on a side of the second sublayer facing the substrate.

14. A display apparatus, comprising a display panel, wherein the display panel comprises:
a substrate;
an isolation structure disposed on one side of the substrate and defining isolation openings in an enclosing manner, the isolation structure comprising a first sublayer and a second sublayer located on a side of the first sublayer facing away from the substrate, the first sublayer having sidewalls facing the isolation openings, and the second sublayer having flange portions protruding from the first sublayer toward the isolation openings;
a plurality of light-emitting devices, at least part of a structure of each of the light-emitting devices being located within a corresponding one of the isolation openings; and
encapsulation portions, each of which is disposed on a side of a corresponding one of the light-emitting devices facing away from the substrate and comprises a first sub-portion and a second sub-portion, the first sub-portion covering the side of the light-emitting device facing away from the substrate, and the second sub-portion covering a corresponding one of the sidewalls;
wherein the second sub-portion has a first thickness which is less than a protruding length of the flange portion, and a ratio of the first thickness to the protruding length of the flange portion is greater than or equal to 0.1 and less than or equal to 0.5.
